(19) United States
(12) Patent Application Publication
(10) Pub. No.: US 2015/0228567 A1
(43) Pub. Date: Aug. 13, 2015

(54) PACKAGE SUBSTRATE AND SEMICONDUCTOR PACKAGE USING THE SAME

(71) Applicant: SAMSUNG ELECTRO-MECHANICS CO., LTD., Suwon-Si (KR)

(72) Inventor: Job Ha, Suwon-Si (KR)

(73) Assignee: SAMSUNG ELECTRO-MECHANICS CO., LTD., Suwon-Si (KR)

(21) Appl. No.: 14/273,306

(22) Filed: May 8, 2014

(30) Foreign Application Priority Data
Feb. 7, 2014 (KR) 10-2014-0014359

(51) Int. Cl. H01L 23/495; H05K 1/02

(52) U.S. Cl. CPC H01L 23/49582; H01L 23/49586; H01L 23/49575; H05K 1/0296; H05K 2201/10204

(57) ABSTRACT

Disclosed herein are a package substrate and a semiconductor package using the same. The package substrate includes a circuit area in which a circuit pattern is formed and a dummy area in which a dummy pattern is formed to surround the circuit area.

### CROSS REFERENCE TO RELATED APPLICATION

This application claims the benefit of Korean Patent Application No. 10-2014-0014359, filed on Feb. 7, 2014, entitled “Package Substrate and Semiconductor Package Using the Same,” which is hereby incorporated by reference in its entirety into this application.

### BACKGROUND OF THE INVENTION

1. Technical Field

The present invention relates to a package substrate and a semiconductor package using the same.

2. Description of the Related Art

Due to the worldwide increase in energy consumption, interests in efficient energy use are continuously increasing. While demands of high integration, high capacity and compact size of a power module which is sensitive to energy efficiency have been increased, the problem of heat dissipation of heat-generating components causes a decrease in the entire performance of the power module. Accordingly, in order to increase an efficiency of a power module and to provide high reliability thereof at the same time, a high heat dissipation package structure with which the above problem of heat dissipation may be solved is required. A key component for a high heat dissipation package structure as described above is the manufacture of a high heat dissipation substrate. In general, a power module is divided into a high power application and a low power application. For a high power application, generally, a plurality of semiconductor devices are mounted on a substrate. Currently, a direct bonded copper (DBC) or a direct bonded aluminum (DBA) having a metal conduction track on a single surface or both surfaces on a ceramic substrate is used in most high power semiconductor modules. Recently, the use of a metal printed circuit board (PCB) having a structure formed by bonding an insulation resin filled with a ceramic-based filler having a high thermal conductivity and a copper sheet onto a metal base has been extended. Although the above-described structure has relatively low insulation performance as compared to a DBC, a DBA, or a ceramic substrate, it is easy to manufacture a substrate at low costs. As a thickness of an insulation resin and a filler component may be modified, heat dissipation performance may be adjusted according to applications, and also, excellent heat dissipation performance is provided.

### PRIOR ART DOCUMENT

(Patent Document 1) Korean Patent Laid-Open Publication No. 2012-0100110

### SUMMARY OF THE INVENTION

The present invention has been made in an effort to provide a substrate in which a dummy area including a dummy pattern is formed around a circuit area including a circuit pattern, so as to prevent cracks in an insulation layer formed under a boundary portion when unit substrates are cut, and a semiconductor package using the package substrate.

According to a preferred embodiment of the present invention, there is provided a package substrate including: a circuit area in which a circuit pattern is formed; and a dummy area in which a dummy pattern is formed to surround the circuit area.

The dummy pattern may be continuously formed along an outer portion of the circuit area.

The dummy pattern may be formed in an outer portion of a corner of the circuit area.

The dummy pattern may be discontinuously formed in an outer portion of the circuit area.

The dummy pattern may be formed of a metal material or an insulation material.

According to another preferred embodiment of the present invention, there is provided a semiconductor package including: a package substrate on which a semiconductor device is mounted; a lead frame that is electrically connected to the package substrate; and a molding unit formed to cover the semiconductor device and the package substrate, wherein the package substrate includes a circuit area in which a circuit pattern is formed and a dummy area in which a dummy pattern is formed to surround the circuit area.

The dummy pattern may be continuously formed along an outer portion of the circuit area.

The dummy pattern may be formed in an outer portion of a corner of the circuit area.

The dummy pattern may be formed of a metal material or an insulation material.

The dummy pattern may be discontinuously formed in an outer portion of the circuit area.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view of a package substrate according to a first preferred embodiment of the present invention;

FIG. 2 is a cross-sectional view of the package substrate according to the first preferred embodiment of the present invention;

FIG. 3 is a plan view of a package substrate according to a second preferred embodiment of the present invention;

FIG. 4 is a plan view of a package substrate according to a third preferred embodiment of the present invention; and

FIG. 5 is a three-dimensional diagram of a semiconductor package according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Package Substrate

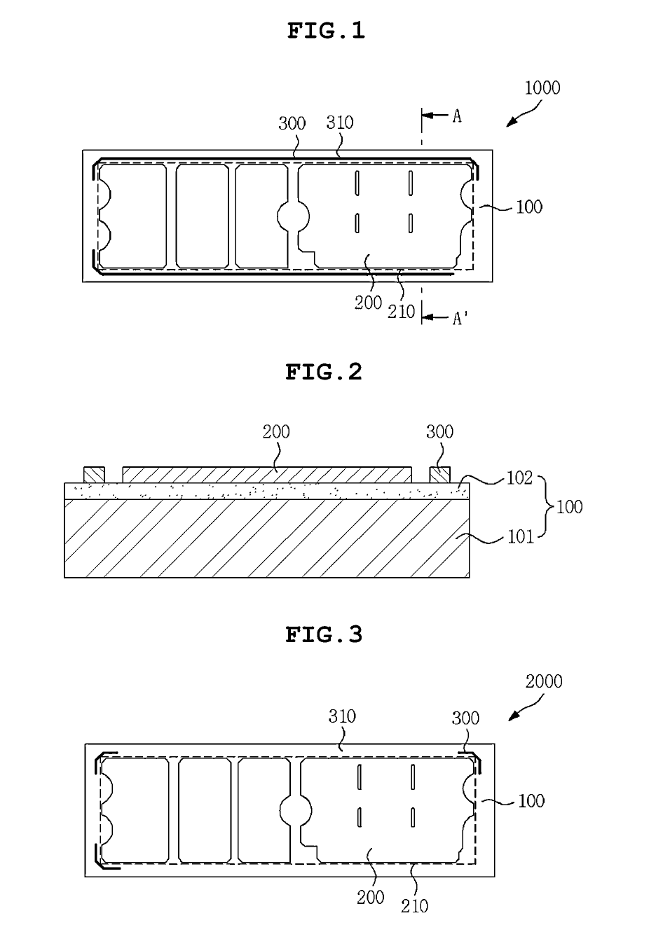

FIG. 1 is a plan view of a package substrate 1000 according to a first preferred embodiment of the present invention.

The package substrate 1000 according to the first preferred embodiment of the present invention includes a circuit area 210 in which a circuit pattern 200 is formed and a dummy area 310 in which a dummy pattern 300 is formed to surround the circuit area 210.

As illustrated in FIG. 1, the dummy pattern 300 may be formed to have various thicknesses in the dummy area 310, and the shape thereof may also be various.

Here, the dummy pattern 300 may be formed along an outer portion of the circuit area 210 so as to be located in a boundary portion to be separated from a unit substrate.

Here, the circuit pattern 200 may function as a path of an electrical signal. The circuit pattern 200 may be formed of any conductive metal used for circuits, and copper is typically used.

Also, the dummy pattern 300 may be formed of a metallic material or an insulation material, but is not limited thereto.

When the dummy pattern 300 is formed of a metallic material, the dummy pattern 300 may be formed to be spaced apart from the circuit area 210. This is in order to avoid electrical contact with the circuit pattern 200. Also, the dummy pattern 300 according to the preferred embodiment of the present invention may be continuously formed in an outer portion of the circuit pattern 200.

Also, the dummy pattern 300 may be formed of an insulation material. For example, the dummy pattern 300 may be formed of an elastic material that is capable of absorbing an external impact, such as an epoxy resin or rubber, but is not limited thereto.

Here, the dummy pattern 300 may be formed together when the circuit pattern 200 is formed. In detail, when an etching operation for patterning the circuit pattern 200 is performed, the dummy pattern 300 may also be patterned.

FIG. 2 is a cross-sectional view of the package substrate 1000 according to the first preferred embodiment of the present invention.

FIG. 2 illustrates an A-A′ cross-section of the package substrate 1000 of FIG. 1.

As illustrated in FIG. 2, the substrate 100 may be formed of a metal plate 101 and an insulation layer 102 formed on a surface of the metal plate 101.

The metal plate 101 may be formed of a metallic material which may be easily available at a relatively low price. For example, the metal plate 101 may be formed of aluminum (Al) or an Al alloy which have thermal conductivity. However, the material of the metal plate 101 is not limited thereto, and any metal having a thermal conductivity may be used.

Here, the insulation layer 102 may be a resin insulation layer. Examples of the resin insulation layer include a thermosetting resin such as an epoxy resin, a thermoplastic resin such as polyimide, or a photocurable resin. Also, the resin insulation layer may also be formed of a resin formed by impregnating a reinforcement material such as glass fibers or an inorganic filler in a thermosetting resin such as prepreg or a thermoplastic resin.

According to the preferred embodiment of the present invention, the circuit pattern 200 and the dummy pattern 300 formed to be separated from the circuit pattern 200 may be formed on the insulation layer 102. A distance between the circuit pattern 200 and the dummy pattern 300 is not limited as long as inter-insulation is provided, and may be selected by one of ordinary skill in the art.

The dummy pattern 300 may be formed along an outer portion of the circuit area 210 so as to be located in a boundary portion to be separated from a unit substrate.

As the dummy pattern 300 is formed in the boundary portion as described above, cracks in the insulation layer 102 formed under the boundary portion due to press cutting may be prevented.

By preventing cracks in the insulation layer 102, defects of the package due to dielectric breakdown which will be described later may be prevented.

FIG. 3 is a plan view of a package substrate 2000 according to a second preferred embodiment of the present invention.

The package substrate 2000 according to the second preferred embodiment of the present invention includes a circuit area 210 in which a circuit pattern 200 is formed and a dummy area 310 in which a dummy pattern 300 is formed to surround the circuit area 210.

As illustrated in FIG. 3, the dummy pattern 300 may be formed in an outer portion of a corner of the circuit area 210.

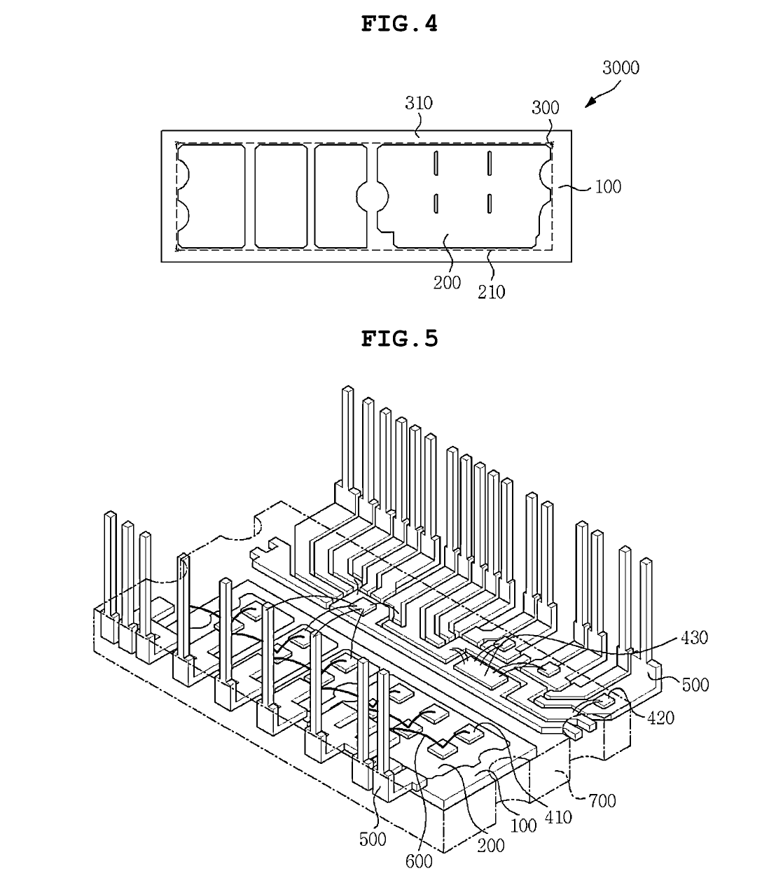

FIG. 4 is a plan view of a package substrate 3000 according to a third preferred embodiment of the present invention.

The package substrate 3000 according to the third preferred embodiment of the present invention includes a circuit area 210 in which a circuit pattern 200 is formed and a dummy area 310 in which a dummy pattern 300 is formed to surround the circuit area 210.

As illustrated in FIG. 4, the dummy pattern 300 may be discontinuously formed in a portion of an outer portion of the circuit area 210.

While the dummy pattern 300 is formed at a corner of the circuit area 210 according to the preferred embodiment of the present invention, the dummy pattern 300 may be formed at a position needed by one of ordinary skill in the art.

Semiconductor Package

FIG. 5 is a three-dimensional diagram of a semiconductor package according to another preferred embodiment of the present invention.

As illustrated in FIG. 5, the semiconductor package according to the preferred embodiment of the present invention includes a package substrate 100 on which a first semiconductor device 410 is mounted, a lead frame 500 that is electrically connected to the package substrate 100, and a molding unit 700 that is formed to cover the first semiconductor device 410 and the package substrate 100; the package substrate 100 includes a circuit area 210 in which a circuit pattern 200 is formed and a dummy area 310 in which a dummy pattern 300 is formed to surround the circuit area 210.

Here, the circuit area 210, the dummy area 310, and the dummy pattern 300 are not shown in FIG. 5. FIGS. 1 through 4 may be referred to for the circuit area 210, the dummy area 310, and the dummy pattern 300 that are not shown here.

Here, the package substrate 100 may be formed of a metal plate and an insulation layer formed on a surface of the metal plate.

The metal plate may be formed of a metallic material which may be easily obtained at a relatively low price. For example, the metal plate may be formed of aluminum (Al) or an Al alloy which have a thermal conductivity. However, the material of the metal plate is not limited thereto, and any metal having a thermal conductivity may be used.

Here, the insulation layer may be a resin insulation layer. Examples of the resin insulation layer include a thermosetting resin such as an epoxy resin, a thermoplastic resin such as polyimide. Also, the resin insulation layer may be formed of a resin that is formed by impregnating a reinforcement material such as glass fibers or an inorganic filler in the resins, for example, prepreg, or a thermosetting resin and/or a photocurable resin, but is not limited thereto.

The dummy pattern 300 may be formed along an outer portion of the circuit area 210 so as to be located in a boundary portion to be separated from a unit substrate.

Also, the dummy pattern 300 may be formed at a corner of the circuit area 210.

Also, the dummy pattern 300 may be discontinuously formed in a portion of the outer portion of the circuit area 210.

While the dummy pattern 300 is formed at a corner of the circuit area 210 according to the preferred embodiment of the present invention, the dummy pattern 300 may be formed at a position needed by one of ordinary skill in the art.

Here, the dummy pattern 300 may be formed of a metallic material or an insulation material, but is not limited thereto.

When the dummy pattern 300 is formed of a metallic material, the dummy pattern 300 may be formed to be separated from the circuit area 210. This is in order to avoid electrical contact with the circuit pattern 200.

Also, the dummy pattern 300 may be formed of an insulation material, for example, an epoxy resin or an elastic material that is capable of absorbing an external impact, such as rubber, but is not limited thereto.

Next, the lead frame 500 formed to contact the package substrate 100 may be electrically connected to the circuit pattern 200 of the circuit area 210.

Here, the lead frame 500 may be formed to be separated from the dummy pattern 300 of the dummy area 310, but is not limited thereto.

In detail, the lead frame 500 may be formed either to be separated from or contact the dummy pattern 300.

When the dummy pattern 300 is formed of a metallic material, the lead frame 500 may be formed to be separated from the dummy pattern 300.

Alternatively, when the dummy pattern 300 is formed of an insulation material, the lead frame 500 may also be formed to contact the dummy pattern 300.

Next, a first semiconductor device 410 may be mounted on the circuit pattern 210. The semiconductor device 410 according to the preferred embodiment of the present invention may be a power device, for example, a device having a large heat value such as an insulated gate bipolar transistor (IGBT) or a diode.

The semiconductor package according to the preferred embodiment of the present invention may further include a second semiconductor device 430.

The second semiconductor device 430 may be mounted on the lead frame 500 that is formed to be separated from the package substrate 100. The second semiconductor device 430 may be a control device such as a control integrated circuit (IC) which has a small heat value.

According to the embodiment of the present invention, the first semiconductor device 410 is mounted on the circuit pattern 200, and the lead frame 500 is mounted on the second semiconductor device 430, but the embodiments of the present invention are not limited thereto. That is, positions at which the first semiconductor device 410 which has a large heat value and the second semiconductor device 430 which has a relatively small heat value are mounted may be modified according to selection of one of ordinary skill in the art.

Also, a wire 600 may be formed so that the first semiconductor device 410 and the second semiconductor device 430 are electrically connected to each other. Also, the wire 600 may electrically connect the first semiconductor device 410 and the lead frame 500.

Also, while not shown in FIG. 5, the wire 600 may electrically connect the second semiconductor device 410 and the lead frame 500. Here, the wire 600 may be formed of aluminum (Al), gold (Au), or copper (Cu), but is not limited thereto. In general, Al may be used as a wire through which a rated voltage, which is a high voltage, is applied to a semiconductor component which is a power device.

Also, a molding unit 700 that surrounds a portion of the lead frame 500 and covers the first semiconductor device 410, the second semiconductor device 430, and the package substrate 100 may be formed.

Here, the molding unit 700 may be formed of, for example, silicone gel or an epoxy molded compound (EMC), but is not limited thereto.

According to the semiconductor package of the preferred embodiment of the present invention, a dummy pattern is formed around a circuit area that includes a circuit pattern so as to prevent cracks in an insulation layer of a boundary portion when unit substrates are cut. Thus, according to the semiconductor package of the preferred embodiment of the present invention, dielectric breakdown of the semiconductor package due to cracks in the insulation layer of the boundary portion may be prevented.

As set forth above, according to the package substrate and the semiconductor package using the same of preferred embodiments of the present invention, a dummy area including a dummy pattern is formed around a circuit area that includes a circuit pattern, thereby preventing cracks in an insulation layer formed under a boundary portion when unit substrates are cut. In addition, the circuit pattern may be protected from an external impact.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A package substrate comprising:
a circuit area in which a circuit pattern is formed; and
a dummy area in which a dummy pattern is formed to surround the circuit area.

2. The package substrate as set forth in claim 1, wherein the dummy pattern is continuously formed along an outer portion of the circuit area.

3. The package substrate as set forth in claim 1, wherein the dummy pattern is formed in an outer portion of a corner of the circuit area.

4. The package substrate as set forth in claim 1, wherein the dummy pattern is discontinuously formed in an outer portion of the circuit area.

5. The package substrate as set forth in claim 1, wherein the dummy pattern is formed of a metal material or an insulation material.

6. A semiconductor package comprising:
a package substrate on which a semiconductor device is mounted;
a lead frame that is electrically connected to the package substrate; and
a molding unit formed to cover the semiconductor device and the package substrate,
wherein the package substrate includes a circuit area in which a circuit pattern is formed and a dummy area in which a dummy pattern is formed to surround the circuit area.

7. The semiconductor package as set forth in claim 6, wherein the dummy pattern is continuously formed along an outer portion of the circuit area.

8. The semiconductor package as set forth in claim 6, wherein the dummy pattern is formed in an outer portion of a corner of the circuit area.

9. The semiconductor package as set forth in claim 6, wherein the dummy pattern is formed of a metal material or an insulation material.

10. The semiconductor package as set forth in claim 6, wherein the dummy pattern is discontinuously formed in an outer portion of the circuit area.
